(19) United States
(12) Patent Application Publication
(10) Pub. No.: US 2025/0031346 A1
(43) Pub. Date: Jan. 23, 2025

(54) SYSTEMS AND METHODS FOR THERMAL MANAGEMENT OF EXTERNALLY MOUNTED ELECTRONIC EQUIPMENT FOR AN AIRCRAFT

(71) Applicant: Smiths Interconnect Inc., Tampa, FL (US)

(72) Inventors: Shawn Kalen O'BRIEN, St. Petersburg, FL (US); James Allan WILKERSON, Jr., Melbourne, FL (US); Ardian Dudi Janura, Moorpark, CA (US)

(21) Appl. No.: 18/852,895

(22) PCT Filed: Sep. 29, 2022
(86) PCT No.: PCT/US2022/045134

§ 371 Date: Sep. 30, 2024

Related U.S. Application Data
(60) Provisional application No. 63/250,642, filed on Sep. 30, 2021.

(51) Int. Cl. H05K 7/20

(52) U.S. Cl. CPC H05K 7/20327

(57) ABSTRACT

A thermal management system is provided. The thermal management system includes a housing extending between a leading end and a trailing end. The housing includes a cooling structure defining at least one inlet, at least one outlet, and a duct coupled in flow communication between the at least one inlet and the at least one outlet. The cooling structure is configured to generate a fluid flow from the at least one inlet to the at least one outlet through the duct in response to the housing moving through a fluid. The thermal management system further includes an electronics assembly disposed in contact with the cooling structure. The cooling structure is configured to transfer heat generated by the electronics assembly to the fluid moving through the duct to cool the electronics assembly.

### BACKGROUND

The embodiments described herein relate generally to thermal management systems and, more particularly, to a thermal management system for cooling of externally mounted electronic equipment on an aircraft.

Electronics assemblies, such transmitters and receivers for electronic communication, may be mounted to the exterior of aircraft. These electronics assemblies must provide adequate cooling for internal circuits to prevent damage caused by overheating. Because there is generally no cooling fluid flow or ability to transfer heat into the aircraft structure, systems located within the aircraft cannot be used to perform this cooling, and airflow around the aircraft must be used. For higher power assemblies, the available outside surface area of the assembly may not be sufficient to transfer enough heat into the airflow to meet the cooling needs of these assemblies. Further, these assemblies must be capable of surviving the airborne environment, meeting structural requirements, and meeting maintenance and safety requirements. In addition, these systems must also perform at low aircraft speed or while the aircraft is stopped at a gate, when limited or no airflow is available. Accordingly, a thermal management system capable of effectively cooling an electronics assemblies mounted on the exterior of an aircraft while maintaining structural integrity is desirable.

### BRIEF SUMMARY

In one aspect, a thermal management system is provided. The thermal management system includes a housing extending between a leading end and a trailing end. The housing includes a cooling structure defining at least one inlet, at least one outlet, and a duct coupled in flow communication between the at least one inlet and the at least one outlet. The cooling structure is configured to generate a fluid flow from the at least one inlet to the at least one outlet through the duct in response to the housing moving through a fluid. The thermal management system further includes an upper housing. The upper housing and the cooling structure define an electronics enclosure. The thermal management system further includes an electronics assembly disposed in the electronics enclosure of the housing in contact with the cooling structure. The cooling structure is configured to transfer heat generated by the electronics assembly to the fluid moving through the duct to cool the electronics assembly.

In another aspect, a method for manufacturing a thermal management system is provided. The method includes forming a cooling structure that defines at least one inlet, at least one outlet, and a duct coupled in flow communication between the at least one inlet and the at least one outlet. The cooling structure is configured to generate a fluid flow from the at least one inlet to the at least one outlet through the duct towards in response to moving through a fluid. The method further includes positioning an electronics assembly in contact with the cooling structure. The cooling structure is configured to transfer heat generated by the electronics assembly to the fluid moving through the duct to cool the electronics assembly. The method further includes coupling an upper housing to the cooling structure to define an electronics enclosure. The electronics assembly is disposed in the electronics enclosure, the upper housing and cooling structure form a housing extending between a leading end and a trailing end, and wherein the cooling structure is configured to cause the fluid to move through the duct.

In another aspect, a housing for a thermal management system is provided. The housing extends between a leading end an a trailing end and includes a cooling structure defining at least one inlet, at least one outlet, and a duct coupled in flow communication between the at least one inlet and the at least one outlet. The cooling structure is configured to generate a fluid flow from the at least one inlet to the at least one outlet through the duct in response to the housing moving through a fluid. The housing further includes an upper housing. The housing and the cooling structure define an electronics enclosure. An electronics assembly is disposed in the electronics enclosure of the housing in contact with the cooling structure, and the cooling structure is configured to transfer heat generated by the electronics assembly to the fluid moving through the duct to cool the electronics assembly.

### BRIEF DESCRIPTION OF THE DRAWINGS

FIGS. 1-7 show example embodiments of the systems and methods described herein.

FIG. 1 is a perspective view of an example thermal management system;

FIG. 2 is a side elevation view of the thermal management system shown in FIG. 1;

FIG. 3 is a plan view of the thermal management system shown in FIGS. 1 and 2;

FIG. 4 is an exploded view of the thermal management system shown in FIGS. 1-3;

FIG. 5 is a cross-sectional view of the thermal management system shown in FIGS. 1-4;

FIG. 6 is a vector diagram illustrating a fluid flow with respect to a vertical cross-section of the thermal management system shown in FIGS. 1-5;

FIG. 7 is a vector diagram illustrating a fluid flow with respect to a horizontal cross-section of the thermal management system shown in FIGS. 1-6;

FIG. 8 is a perspective view of an example transmitter array for use in the thermal management system shown in FIGS. 1-7; and

FIG. 9 is a flowchart of an example method of manufacturing the thermal management system shown in FIGS. 1-7.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, is applied to modify any quantitative representation that could permissibly vary without resulting in a change in the basic function to which it is related. Accordingly, a value modified by a term or terms, such as “about”, “approximately”, and “substantially”, is not to be limited to the precise value specified. In at least some instances, the approximating language may correspond to the precision of an instrument for measuring the value. Here and throughout the specification and claims, range limitations are combined and interchanged, such ranges are identified and include all the sub-ranges contained therein unless context or language indicates otherwise.

The disclosed systems and methods include a thermal management system including a housing having a leading end and a trailing end. The housing may be mounted on an exterior surface of an aircraft, with the leading end oriented towards a front of the aircraft, and the trailing end oriented towards a rear of the aircraft. The housing includes a cooling structure defining at least one inlet, at least one outlet, and a duct coupled in flow communication between the at least one inlet and the at least one outlet. The cooling structure is configured to generate a fluid flow from the at least one inlet to the at least one outlet through the duct in response to the housing moving through a fluid such as air. In some embodiments, the at least one inlet is located closer to the trailing end than the outlet, so that air generally moves through the duct in a direction that is the same as the direction of movement of the aircraft.

The housing also includes an upper housing (sometimes referred to herein as a “radome”) that defines an electronics enclosure with the cooling structure. The thermal management system further includes an electronics assembly disposed in the electronics enclosure of the housing. The electronics assembly includes electronic components that generate heat, such as steered antenna arrays and associated transmitter and receiver circuitry. The electronics assembly is in contact with the cooling structure, so that the cooling structure transfers heat generated by the electronics assembly to the fluid moving through the duct to cool the electronics assembly. In certain embodiments, the cooling structure also includes a phase change thermal storage material, such as paraffin wax, that stores heat generated by the electronics assembly at a constant temperature by changing from a solid phase to a liquid phase.

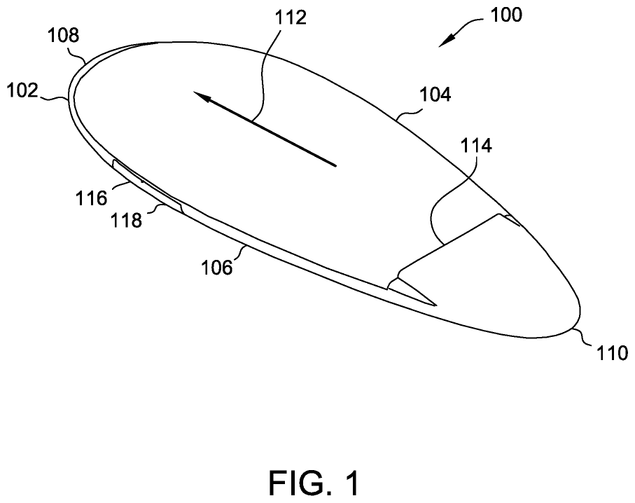

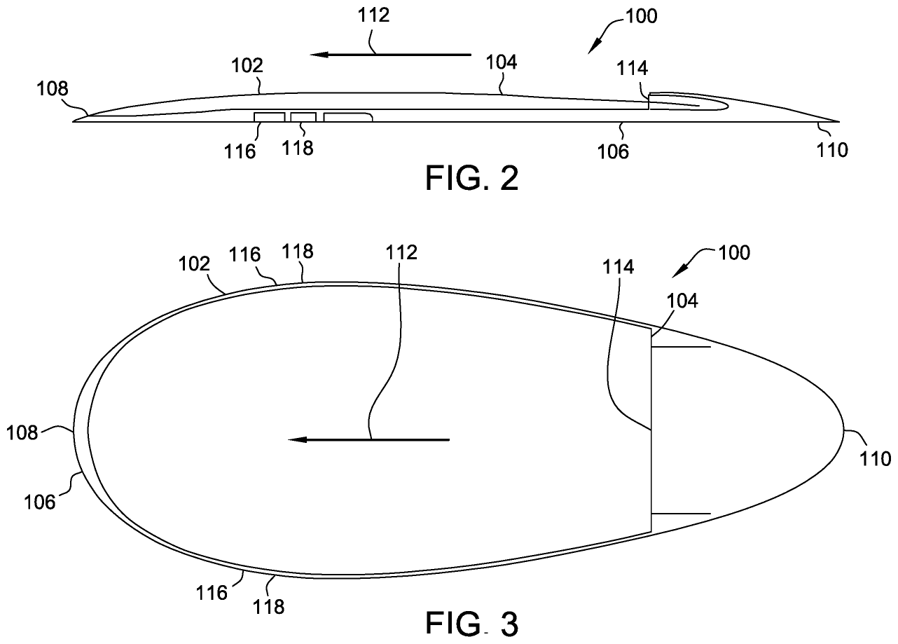

FIGS. 1-3 illustrate an example thermal management system 100. Thermal management system 100 includes a housing 102, which, in some embodiments, includes a radome 104 and a lower housing 106. Lower housing 106 is configured to be attached to an external surface of a moving vehicle or machine such as an aircraft. Housing 102 has a leading end 108 and a trailing end 110 with respect to a forward direction 112 of movement of the aircraft or other vehicle on which housing 102 is mounted.

Radome 104 is shaped to reduce drag and turbulence in order to reduce heating resulting from friction and to reduce effects on aircraft flight characteristics. In certain embodiments, such as those in which thermal management system 100 includes RF transmitting and receiving elements, radome 104 is constructed of composite materials that achieve a defined and desired RF performance. Thermal and aerodynamic performance of thermal management system 100 depend on a geometric shape of the radome 104 and housing 102 and surface characteristics of radome 104. For example, an absorption coefficient of radome 104 may vary from 0.15 for white painted surface to 0.45 dark gray painted surface. In some embodiments, radome 104 includes thermal insulation or is otherwise configured to reduce heat from solar radiation reaching components located within housing 102, enabling thermal management system 100 to maintain cooling efficiency under high solar thermal loads.

Housing 102 defines an inlet 114 and at least one outlet 116, which are coupled in flow communication via a duct 118. Accordingly, as housing 102 moves through a fluid such as air in forward direction 112, the fluid flows into housing 102 via inlet 114, through duct 118, and out of housing 102 via outlet 116. In some embodiments, as shown in FIG. 1, inlet 114 is located proximate to trailing end 110 of housing 102, and outlet 116 is located forward of inlet 114, nearer to leading end 108. Alternatively, inlet 114 and outlet 116 may each either be located near leading end 108 or trailing end 110, and either inlet 114 or outlet 116 may be located nearer to leading end 108. Inlet 114 and outlet 116 are shaped and positioned to maintain structural integrity in the event of impact events, such as bird strikes. For example, inlet 114 and/or outlet 116 may be positioned such that 114 and/or outlet 116 are within a boundary layer of the aircraft and are shielded from direct impact, such as by being positioned on a side-facing portion of housing 102 near an outer surface of the aircraft. In certain embodiments, inlet 114 is located on an upper surface of housing 102, adjacent to radome 104, and outlet 116 is located on a side-facing surface of housing 102.

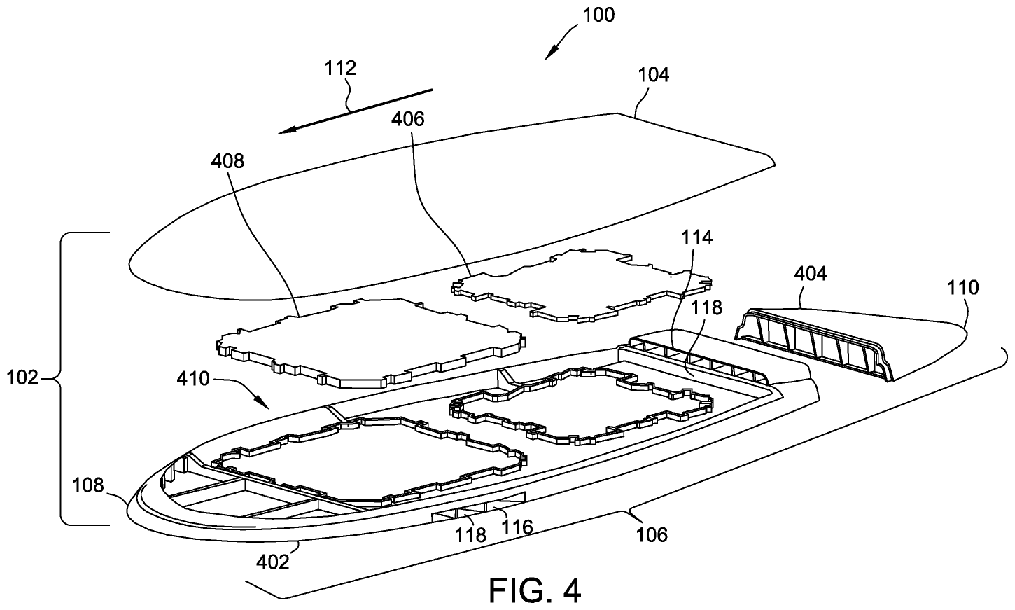

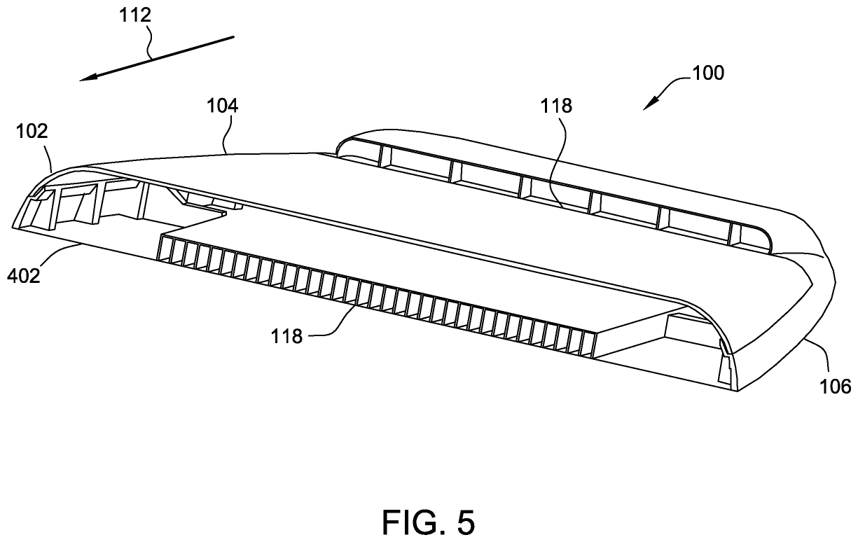

FIG. 4 is an exploded view of thermal management system 100, and FIG. 5 is a cross-sectional view of thermal management system 100. As shown in FIG. 4, lower housing 106 includes a cooling structure 402 and an aft fairing 404. Inlet 114, outlet 116, and duct 118 are defined in cooling structure 402. Thermal management system 100 further includes a transmitter array 406 and a receiver array 408, which are disposed within an environmentally sealed electronics enclosure 410 formed by radome 104 and lower housing 106. Transmitter array 406 and receiver array 408 each include respective arrays of antennas and other active and passive components for transmitting and receiving electronic communications signals such as pulse-code modulation (PCM) signals. These components generate heat, which may be dissipated into air moving through duct 118 to cool transmitter array 406 and receiver array 408. Transmitter array 406 and receiver array 408 are positioned in contact with cooling structure 402, such that heat may passively transfer from transmitter array 406 and receiver array 408, through cooling structure 402, and into air moving through duct 118.

As shown in FIG. 5, in some embodiments, cooling structure 402 includes cooling fins 502 that increase a surface area of duct 118 to facilitate a greater transfer of heat. Because cooling structure 402 is directly coupled to the heat sources of transmitter array 406 and receiver array 408, thermal management system may not include additional passive heat transfer components. Further, no active cooling components are present within housing 102, and no heat load is transferred to the aircraft fuselage.

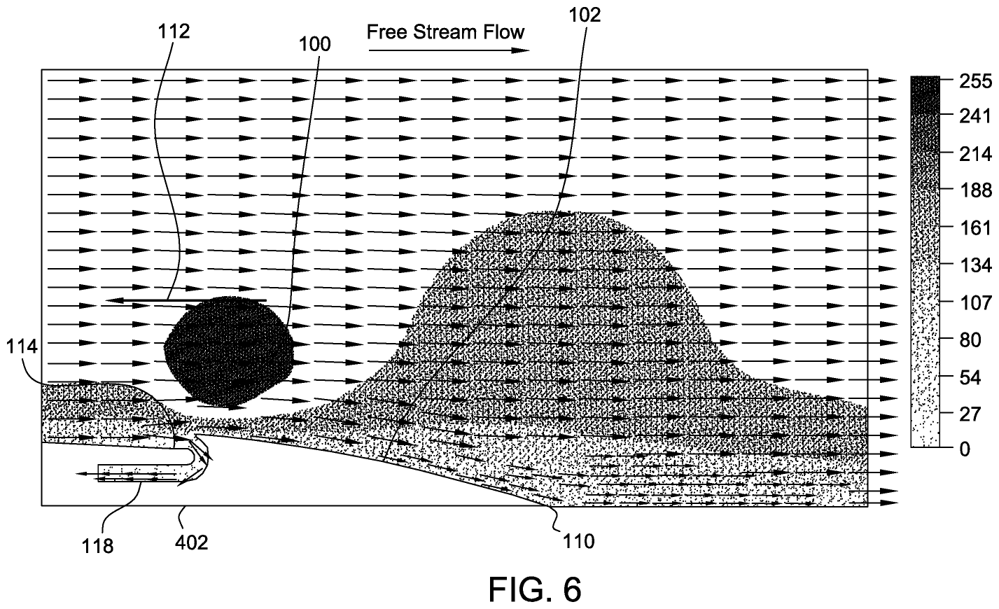

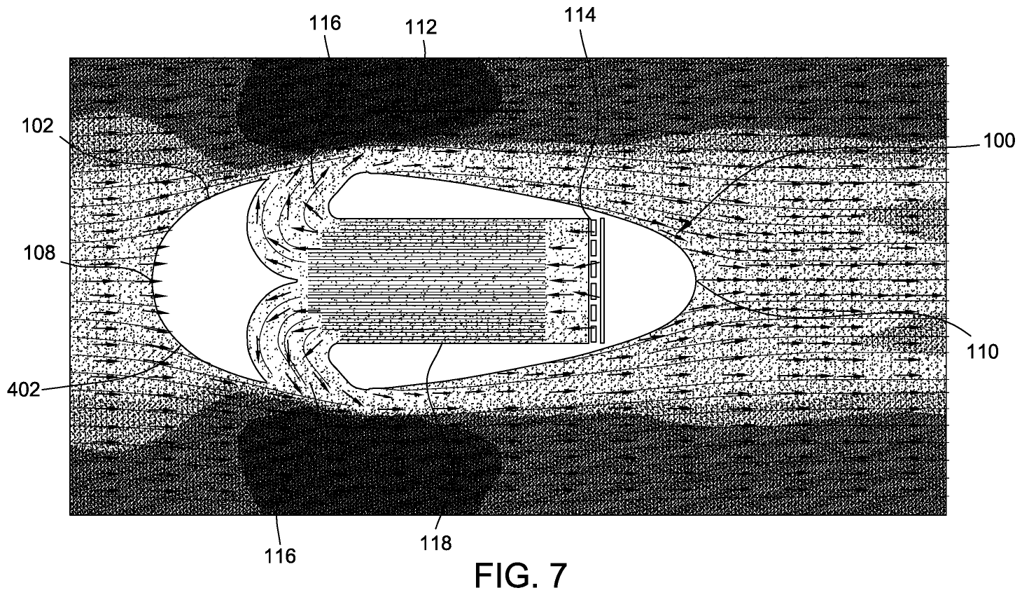

FIGS. 6 and 7 are vector diagrams illustrating a fluid flow through housing 102. As shown in FIG. 6, fluid, such as air, moves into duct 118 at inlet 114. Duct 118 guides the fluid to flow through housing 102 from trailing end 110 towards leading end 108. In other words, air moves through duct 118 in the same forward direction 112 of movement as housing 102. In some embodiments, air slightly accelerates as it moves through duct 118. In certain embodiments, an airflow velocity within duct 118 is well below freestream velocity, which reduces levels of induced acoustic pressure that is generated due to air passage through narrow channels.

Further, as shown in FIG. 7, the fluid moves between cooling fins 502 to cool transmitter array 406 and receiver array 408 through cooling structure 402 before laterally exiting housing 102 at outlet 116. In some embodiments, duct 118 has a high aspect ratio, in that a width of duct 118 is greater than a height of duct 118, which enables housing 102 to have a low profile and overall height for reduced aerodynamic effects. After exiting outlet 116, air moves into an external low-pressure region, which reduces flow shearing effects and turbulence.

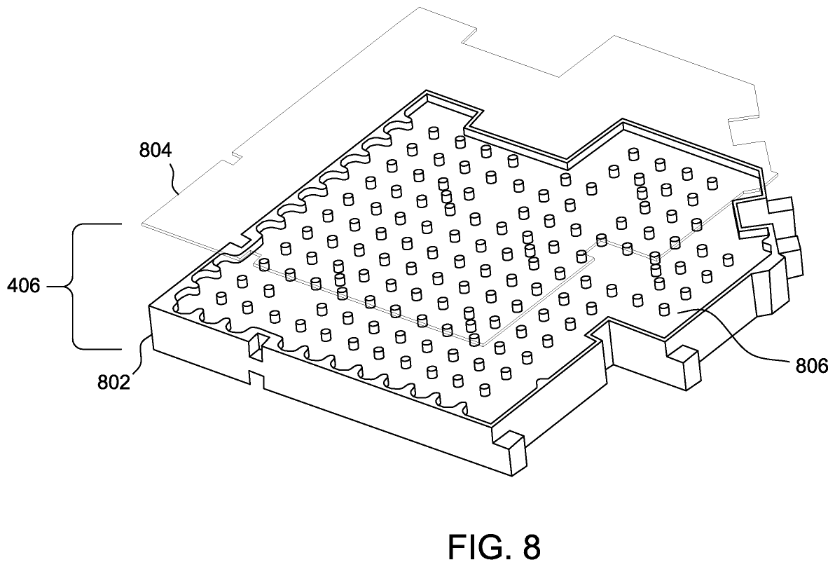

FIG. 8 is a perspective view of an example transmitter array 406. In certain embodiments, receiver array 408 has a similar structure to transmitter array 406 as shown in FIG. 8. Transmitter array 406 includes a lid 802 and a mounting base 804.

In some embodiments, transmitter array 406 further includes a phase-change thermal storage material 806 disposed in contact with mounting base 804. Additionally or alternatively, thermal storage material such as phase-change thermal storage material 806 may be disposed at different locations within thermal management system 100, which enables thermal management system 100 to cool electronic components such as transmitter array 406 and receiver array 408 under low airflow conditions, such as when the aircraft on which thermal management system 100 is mounted is taxiing or at a gate. Phase-change thermal storage material 806 may be, for example, a paraffin wax material that melts to store heat during low airflow conditions, and becomes solid during high airflow conditions to dissipate the heat to the air through cooling structure 402. The phase-change characteristic of phase-change thermal storage material 806 enables heat to be stored at a constant temperature (i.e., the melting temperature of the phase-change thermal storage material). The critical temperature of phase-change thermal storage material 806 may be tailored to meet the requirements of a specific operating environment and temperature limits of the electronic equipment. For example, a melting point of paraffin wax varies with molecular weight, so wax compositions with melting points between 50 degrees Celsius and 75 degrees Celsius may be readily obtained. A mass of phase-change thermal storage material 806 may be selected to allow sufficient time for the equipment to operate when the aircraft is at the gate or during taxi operations without exceeding a maximum operating temperature. In other words, phase-change thermal storage material 806 should be sufficiently massive such that it continues to store heat for the duration of the low airflow conditions without increasing in temperature by becoming melted entirely.

In addition, in certain embodiments, thermal management system 100 is configured to use phased power reduction strategies to extend time in which temperature may be controlled in low airflow conditions. For example, transmitter array 406 and/or receiver array 408 may be operated in a low power mode, in which non-essential functions of transmitter array 406 and receiver array 408 are switched off and remaining critical functions operated in lower power modes. This can include, for example, operation at lower transmit duty cycle, shutdown of antenna elements in transmitter array 406 and/or receiver array 408 (e.g., using a sparsely-populated array concept), reduction of peak transmit power, and/or shutdown of non-essential functions.

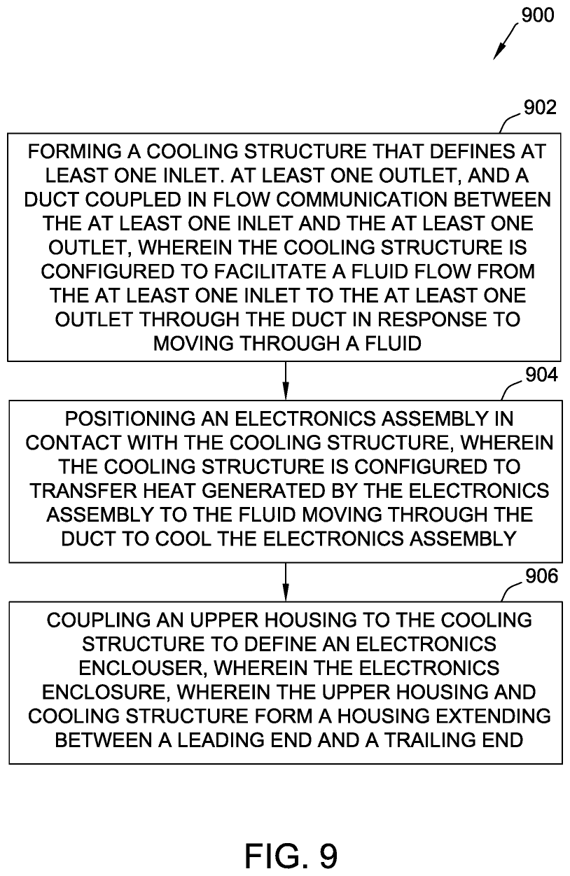

FIG. 9 is a flowchart of an example method 900 for manufacturing a thermal management system such as thermal management system 100. Method 900 includes forming 902 a cooling structure (such as cooling structure 402) that defines at least one inlet (such as inlet 114), at least one outlet (such as outlet 116), and a duct (such as duct 118) coupled in flow communication between the at least one inlet and the at least one outlet. The cooling structure is configured to generate a fluid flow from the at least one inlet to the at least one outlet through the duct in response to moving through a fluid, for example, by moving through air by being mounted on an exterior surface of an aircraft.

Method 900 further includes positioning 904 an electronics assembly (such as transmitter array 406 and/or receiver array 408) in contact with the cooling structure. The cooling structure is configured to transfer heat generated by the electronics assembly to the fluid moving through the duct to cool the electronics assembly.

Method 900 further includes coupling 906 an upper housing (such as radome 104) to the cooling structure to define an electronics enclosure (such as electronics enclosure 410). The electronics assembly is disposed in the electronics enclosure, and the upper housing and cooling structure form a housing (such as housing 102) extending between a leading end (such as leading end 108) and a trailing end (such as trailing end 110).

In some embodiments, the at least one inlet is located closer to the trailing end of the housing that the at least one outlet, and the cooling structure is configured to cause the fluid to move through the duct towards the leading end.

In certain embodiments, the cooling structure includes a phase change thermal storage material configured to store heat generated by the electronics assembly at a constant temperature by changing from a solid phase to a liquid phase.

Example embodiments of methods and systems for thermal management of electronic components are described above in detail. The methods and systems are not limited to the specific embodiments described herein, but rather, components of systems and/or steps of the methods may be used independently and separately from other components and/or steps described herein. Accordingly, the example embodiments can be implemented and used in connection with many other applications not specifically described herein.

Technical effects of the systems and methods described herein include at least one of: (a) improved cooling of electronic components mounted on an aircraft by utilizing a housing defining a duct configured to generate an airflow in a direction opposite a direction of motion of the aircraft to transfer heat from the electronic components; and (b) improved cooling of electronic components mounted on an aircraft in low airflow conditions by utilizing a phase change thermal storage material configured to store heat at a constant temperature by changing from a solid phase to a liquid phase.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose various embodiments, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A thermal management system comprising:
a housing extending between a leading end and a trailing end, said housing comprising:
a cooling structure defining at least one inlet, at least one outlet, and a duct coupled in flow communication between the at least one inlet and the at least one outlet, wherein said cooling structure is configured to generate a fluid flow from the at least one inlet to the at least one outlet through the duct in response to said housing moving through a fluid; and
an upper housing, said upper housing and said cooling structure defining an electronics enclosure; and
an electronics assembly disposed in the electronics enclosure of said housing in contact with said cooling structure, wherein said cooling structure is configured to transfer heat generated by said electronics assembly to the fluid moving through the duct to cool said electronics assembly.

2. The thermal management system of claim 1, wherein the at least one inlet is located closer to the trailing end of said housing than the at least one outlet.

3. The thermal management system of claim 1, wherein said cooling structure further comprises a phase change thermal storage material configured to store heat generated by said electronics assembly by changing from a solid phase to a liquid phase.

4. The thermal management system of claim 3, wherein said phase change thermal storage material comprises a paraffin wax material.

5. The thermal management system of claim 3, wherein said phase change thermal storage material has a melting point in a range from 50 degrees Celsius to 75 degrees Celsius.

6. The thermal management system of claim 1, wherein said cooling structure comprises a plurality of cooling fins extending into the duct.

7. The thermal management system of claim 1, wherein the electronics enclosure is disposed between said upper housing and the duct defined by said cooling structure.

8. The thermal management system of claim 1, wherein said upper housing comprises thermal insulation.

9. The thermal management system of claim 1, wherein the at least one inlet is disposed on an upper surface of said cooling structure.

10. The thermal management system of claim 1, wherein the at least one outlet is disposed on a side-facing surface of said cooling structure.

11. The thermal management system of claim 1, wherein the fluid is air.

12. The thermal management system of claim 1, wherein said housing is attached to an exterior surface of an aircraft.

13. The thermal management system of claim 1, wherein said electronics assembly comprises at least one of a transmitter array and/or a receiver array.

14. The thermal management system of claim 1, wherein said electronics assembly is configured to operate in a low power mode when said housing is not moving through the fluid.

15. A method for manufacturing a thermal management system, said method comprising:
forming a cooling structure that defines at least one inlet, at least one outlet, and a duct coupled in flow communication between the at least one inlet and the at least one outlet, wherein the cooling structure is configured to generate a fluid flow from the at least one inlet to the at least one outlet through the duct in response to moving through a fluid;
positioning an electronics assembly in contact with the cooling structure, wherein the cooling structure is configured to transfer heat generated by the electronics assembly to the fluid moving through the duct to cool the electronics assembly; and
coupling an upper housing to the cooling structure to define an electronics enclosure, wherein the electronics assembly is disposed in the electronics enclosure, wherein the upper housing and cooling structure form a housing extending between a leading end and a trailing end, and wherein the cooling structure is configured to cause the fluid to move through the duct.

16. The method of claim 15, wherein the at least one inlet is located closer to the trailing end of the housing that the at least one outlet.

17. The method of claim 16, wherein the cooling structure includes a phase change thermal storage material configured to store heat generated by the electronics assembly by changing from a solid phase to a liquid phase.

18. A housing for a thermal management system, said housing extending between a leading end an a trailing end and comprising:
a cooling structure defining at least one inlet, at least one outlet, and a duct coupled in flow communication between the at least one inlet and the at least one outlet, wherein said cooling structure is configured to generate a fluid flow from the at least one inlet to the at least one outlet through the duct in response to said housing moving through a fluid; and
an upper housing, said upper housing and said cooling structure defining an electronics enclosure, wherein an electronics assembly is disposed in the electronics enclosure of the housing in contact with said cooling structure, and wherein said cooling structure is configured to transfer heat generated by the electronics assembly to the fluid moving through the duct to cool the electronics assembly.

19. The housing of claim 18, wherein the at least one inlet is located closer to the trailing end of said housing that the at least one outlet.

20. The housing of claim 18, wherein said cooling structure further comprises a phase change thermal storage material configured to store heat generated by the electronics assembly by changing from a solid phase to a liquid phase.
